(19) United States
(12) Patent Application Publication
(10) Pub. No.: US 2008/0230764 A1
(43) Pub. Date: Sep. 25, 2008

(54) Composite Quantum Dot Structures

(75) Inventor: Michael G Burt, Suffolk (GB)

Correspondence Address: BANNER & WITCOFF, LTD., 1100 13th STREET, N.W., SUITE 1200, WASHINGTON, DC, 20005-4051, US

(73) Assignee: Trackdale Ltd., Framlingham (GB)

(21) Appl. No.: 10/589,756

(22) PCT Filed: Feb. 28, 2005
(86) PCT No.: PCT/EP05/50840

§ 371 Date: Jun. 3, 2008

(30) Foreign Application Priority Data
Feb. 27, 2004 (GB) 0404442.6

(51) Int. Cl. H01L 29/06; H01L 21/34

(52) U.S. Cl. 257/12; 438/478; 977/774; 977/890

(57) ABSTRACT

A composite quantum dot structure (4) comprises a charge carrier confinement region, such as a quantum dot (2), a barrier (5) and an electrically conductive layer (3). This structure allows the dimensions of the conductive layer (3) to be substantially independent of the size of the region (2), so that the dimensions of the region (2) can thus be selected in order to achieve desired optical properties, while the electrically conductive layer (3) can be of sufficient thickness to ensure that it can be reliably deposited. The structure may also include a cladding layer (7) (FIG. 4) to compensate for any lack of chemical affinity between the barrier (5) and conductive layer (3). An ensemble of such structures be provided in which the quantum dots (1) have various radii but the dimensions of the conductive layers (3) and the overall dimensions of the structures are substantially uniform, e.g. for use in an amplifier configured to amplify light of various wavelengths.

### BACKGROUND OF THE INVENTION

The invention relates to a quantum dot structure comprising a quantum dot coated with a layer of electrically conductive material.

Quantum dots have wide range of possible uses in optoelectronic devices, such as amplifiers, lasers, light-emitting diodes, modulators and switches. Their attractiveness comes from the discrete nature of their electronic energy spectrum, which reduces inefficiency due to thermal agitation, and the fact that the spectrum can be engineered via both chemical composition and size.

Quantum dots made by colloidal chemistry have the further attraction of possible incorporation in a range of host materials by the use of surfactant or linker molecules; the molecule is chosen to have a functional group at its exterior end that renders the quantum dot soluble in the chosen host such as a polymer or glass.

There is a lot of prior art, going back about a century or so, on the distortion of electromagnetic fields due to the presence of metallic regions in composite structures. In particular, Birnboim & Neeves (U.S. Pat. No. 5,023,139) teach how metal nanoparticles and nanoparticles coated with metal layers and variations thereon, provide a means of modifying electric fields within and in the neighbourhood of nanoparticles and that such effects can be used to advantage in optoelectronic devices. The modification of the electric fields is closely connected to the existence of plasma related resonances. A recent paper by a group at Rice University, Houston, [Science 302 419 (2003), 17 Oct.], has reported making silica-gold-silica-gold nanoparticles and measurements of the plasma related resonant frequencies thereof. This paper is an example of the present understanding of how to apply standard electromagnetic theory to the design of nanostructures containing metal layers albeit couched in the language of molecular orbital theory. This standard theory is due to Mie and Debye (see e.g. Born & Wolf 1980, ‘Principles of Optics’, Pergamon or Bohren & Huffman 1983, ‘Absorption and Scattering of Light by Small Particles’ Wiley).

This prior art, however, considers the materials to be continuous, ignoring any atomic granularity, and assumes that it is possible, in principle at least, to make a layer of material of arbitrary thickness when in fact it is only possible to achieve an integer multiple of the inter atomic or molecular spacing. But this is a serious impediment to the implementation of the prior art to optoelectronic devices using nanoparticles or quantum dots. For instance, suppose one wished to use the prior art to maximize the electric field inside a quantum dot to increase optical gain or the efficacy of an optical pumping beam. One would consider a simple example, as shown in FIG. 1, in which a quantum dot structure 1 consists of a quantum dot 2 coated with a layer 3 of metal, such as a noble metal (copper, silver or gold) to form a metal shell, and use the above mentioned standard electromagnetic theory in the dipole approximation to calculate the electric field created inside the quantum dot due to the presence of a plane electromagnetic wave incident thereon.

The quantum dot 2 of the prior quantum dot structure 1 may be made of a semiconductor or insulator, such as a III-V or II-VI compound, for example, mercury telluride or sulphide. A structure such as that shown in FIG. 1 can be made by first creating the quantum dot 2 in colloidal solution and then introducing reagents to allow the metal layer to form. If the quantum dot 2 were made of mercury telluride for example, then one would introduce a gold salt and hydrogen telluride to form a layer of gold telluride and then introduce a reducing agent to convert the gold telluride layer to gold.

In FIG. 2, the enhancement factor, which represents the squares of the ratios of the electric field inside the quantum dot 2 with and without the metal layer 3, are plotted as functions of delta, where delta represents the ratio of the metal layer 3 width to the radius of the quantum dot 2.

Typical values for the dielectric constants have been used to calculate the enhancement factor. For the host medium we have taken a dielectric constant of 3, typical in magnitude for a glass or polymer host. For the quantum dot material, we have taken a typical dielectric constant of 12 for a semiconductor. And for the metal layer 3 we have taken a dielectric constant of −90+7.5i, typical of that for a noble metal at telecoms wavelengths (1300 to 1500 nm). However, the precise values are not important, because the main feature of the curve, a sharp maximum at about delta=0.1, is remarkably robust to parameter changes.

Now, in order to obtain the desirable properties of quantum dots, such as their discrete energy levels in the absence of broadening of the levels due to lifetime effects etc (but in practice quasi discrete), the quantum dot radius needs typically to be 5 nm or less. That means, according to the results presented above based on prior art, that the metal layer needs to be only about 0.5 nm thick or less. Typically, the atomic spacing in noble metals is about 0.25 nm. So a 0.5 nm thick layer corresponds to 2 atoms! If one was trying to optimise, simultaneously, the gain produced by an ensemble of quantum dots with radii ranging from 2.5 nm to 5 nm, as one would wish to do for, say, a quantum dot amplifier that could simultaneously amplify all wavelengths (a range of about 400 nm) in the recent ITU Coarse Wavelength Division Multiplex standard, then, while one monolayer of metal would maximise the electric field in quantum dots of radius 2.5 nm, it would not do so for the rest of the ensemble. And similarly if two atomic layers were deposited on all the quantum dots, then those with radius 5 nm would display optimum gain, but all the other quantum dots in the ensemble would not be optimised. So it is impossible with such thin layers to optimise an ensemble of quantum dots. At such thin layers one has lost a vital flexibility in the design assumed by the prior art. And this does not take into account the difficulties, especially in manufacture, of obtaining a uniform layer with a precise number of monolayers, even if it were possible in principle.

A potential solution to the problem is to increase the radius of the metal layer 3 so that the resonance condition, typically internal radius of the metal layer 3 equal to approximately ten times its width in the above example, corresponds to layer thickness for which the atomic granularity in no longer a problem. But just increasing the size of the quantum dot 2 by a factor, say, of ten is not an option, as the valuable quantisation of the energy levels in the quantum dots 2 would be lost.

### SUMMARY OF THE INVENTION

The problem of retaining the desirable properties of a quantum dot structure, while still obtaining the benefits of the metal layer 3, is addressed by the present invention as follows.

According to a first aspect of the invention, a composite quantum dot structure comprises a charge carrier confinement region formed of a first material, a barrier formed of a second material other than the first material and arranged to confine charge carriers within the charge carrier confinement region and a layer of electrically conductive material surrounding said charge carrier confinement region and said barrier.

For example, the quantum dot structure may comprise a charge carrier confinement region in the form of a quantum dot, surrounded by a barrier formed by a layer of the second material, so that the barrier prevents electrons and/or holes from leaving the charge carrier confinement region. Alternatively, the quantum dot structure may comprise a barrier in the form of a core, which is surrounded by the charge carrier confinement region.

The composite quantum dot structure permits the inner and outer radii of the layer of electrically conductive material to be substantially independent of the radius of the charge carrier confinement region. Thus, the dimensions of the charge carrier confinement region can be selected in order to achieve its desired optical properties while permitting the use of a layer of electrically conductive material of a thickness such that it can be reliably deposited.

The composite quantum dot structure also permits the provision of an ensemble of structures in which the dimensions of the charge carrier confinement regions and of the barriers vary between the structures so that the thicknesses of the layers of electrically conductive material and the overall dimensions of the structures in the ensemble are substantially uniform. Such an ensemble may be used in a quantum dot amplifier configured to amplify light with a variety of wavelengths.

The first material and/or the second material may be a semiconductor.

Where both the first and second materials are semiconductors, the second material may have a band gap that is wider than that of the first material.

The first material and/or the second material may be an insulator.

The first material and/or the second material may be a semi-insulator.

A cladding layer may be provided, located adjacent to the inner radius of the layer of electrically conductive material. The cladding layer may compensate for any lack of chemical affinity between the electrically conducting material and the adjacent material, in other words, between the first or second material, depending on whether the charge carrier confinement region or the barrier is adjacent to the electrically conductive layer. The cladding layer may be formed of a semiconducting material, an insulating material or a semi-insulating material. Multiple cladding layers may be provided, wherein at least two of said cladding layers of formed of different materials.

The electrically conductive material may be a metal, such as a noble metal.

The quantum dot structure may be substantially spherically symmetrical. In the case where the charge carrier confinement region is a quantum dot and is surrounded by the barrier, the inner radius of the layer of electrically conductive material may be approximately ten times the radius of the quantum dot.

In a substantially spherically symmetrical structure, in which the charge carrier confinement region is a quantum dot and is surrounded by the barrier, the quantum dot may have a radius of 5 nm or less.

This aspect also provides an optical amplifier, a laser, a light-emitting diode and an optical switch comprising one or more of said quantum dot structures.

According to a second aspect of the invention, a method of producing a composite quantum dot structure comprises providing a charge carrier confinement region formed of a first material, providing a barrier arranged to confine charge carriers to said charge carrier confinement region, formed of a second material, other than the first material and providing a layer of electrically conductive material surrounding said charge carrier confinement region and said barrier.

The method may comprise providing one or more cladding layers adjacent to said layer of electrically conductive material. Where multiple cladding layers are provided, at least two of the cladding layers may be formed of different materials.

The method may further include incorporating said quantum dot structure in a host material.

The method may be used to produce an ensemble of quantum dot structures, by physically dividing an ensemble of charge carrier confinement regions into sub-ensembles and reconstituting said ensemble of charge carrier confinement regions, wherein the steps of providing said barrier and providing said layer of electrically conductive material are performed on the sub-ensembles of charge carrier confinement regions, before said step of reconstituting said plurality of charge carrier confinement regions. The ensemble may be divided into the sub-ensembles using a size fractionation process. The method may also include providing one or more cladding layers on the barriers within said sub-ensembles.

Alternatively, the method may be used to produce an ensemble of quantum dot structures, by physically dividing an ensemble of barriers into sub-ensembles and reconstituting said ensemble of barriers, wherein the steps of providing said charge carrier confinement regions and providing said layer of electrically conductive material are performed on the sub-ensembles of barriers, before said step of reconstituting said plurality of barriers. The ensemble may be divided into the sub-ensembles using a size fractionation process. The method may also include providing one or more cladding layers on the charge carrier confinement regions within said sub-ensembles.

According to a third aspect of the invention, an ensemble of quantum dot structures comprises a first quantum dot structure comprising a charge carrier confinement region formed of a first material and having first dimensions and a barrier formed of a second material and having second dimensions, arranged to confine charge carriers to said charge carrier confinement region, said first material being different from said second material, wherein one of said charge carrier confinement region and said barrier surrounds the other of said charge carrier confinement region and said barrier, and a second quantum dot structure comprising a charge carrier confinement region, formed of the first material and having third dimensions, and a barrier, formed of the second material and having fourth dimensions, arranged to confine charge carriers to said charge carrier confinement region, wherein one of said charge carrier confinement region and said barrier surrounds the other of said charge carrier confinement region and said barrier, said third dimensions being different from said first dimensions and said fourth dimensions being different from said second dimensions, wherein each of said first and second quantum dot structures comprise a layer of electrically conductive material, surrounding said one of said charge carrier confinement region and said barrier, the dimensions of said layers of electrically conductive material of the first and second quantum dot structures being substantially the same.

At least one of said first and second quantum dot structures may comprise a cladding layer located between the layer of electrically conductive material and either said barrier or said charge carrier confinement region.

This aspect also provides an optical amplifier, a laser and a light-emitting diode comprising such an ensemble.

According to a fourth aspect of the invention, a method of producing an ensemble of quantum dot structures comprises providing a plurality of charge carrier confinement regions formed of a first material, at least a first one of said charge carrier confinement regions having first dimensions and at least a second one of said charge carrier confinement regions having second dimensions, wherein the first dimensions are not equal to the second dimensions, providing a plurality of barriers, each one of said barriers being arranged to confine charge carriers to a respective one of said charge carrier confinement regions, the barriers being formed of a second material other than the first material, and providing a plurality of layers of electrically conductive material, wherein, in each quantum dot structure, one of said barrier and said charge carrier confinement regions surrounds the other of said barrier and said charge carrier confinement region, each layer of electrically conductive material surrounding a respective barrier and charge carrier confinement region, and said first, second, third and fourth dimensions are selected so that the dimensions of said layers of electrically conductive material is substantially the same.

At least one of said first and second quantum dot structures may comprise a cladding layer located between the layer of electrically conductive material and said one of said barrier and said charge carrier confinement region.

### BRIEF DESCRIPTION OF THE DRAWINGS

The invention will be further described, by way of example, with reference to the accompanying drawings, of which:

FIG. 1 depicts a prior art quantum dot structure;

FIG. 2 is a graph showing the relationship between the enhancement factor and delta for the prior art quantum dot structure of FIG. 1;

FIG. 3 depicts a quantum dot structure according to a first embodiment of the invention;

FIG. 4 depicts a quantum dot structure according to a second embodiment of the invention;

FIG. 5 depicts a quantum dot structure according to a third embodiment of the invention;

FIG. 6 depicts a quantum dot structure according to a fourth embodiment of the invention;

FIG. 7 depicts an ensemble of quantum dot structures according to the invention;

FIG. 8 is a schematic diagram of an amplifier comprising the ensemble of quantum dot structures shown in FIG. 7; and

FIG. 9 is a schematic diagram of another amplifier comprising the ensemble of quantum dot structures shown in FIG. 7.

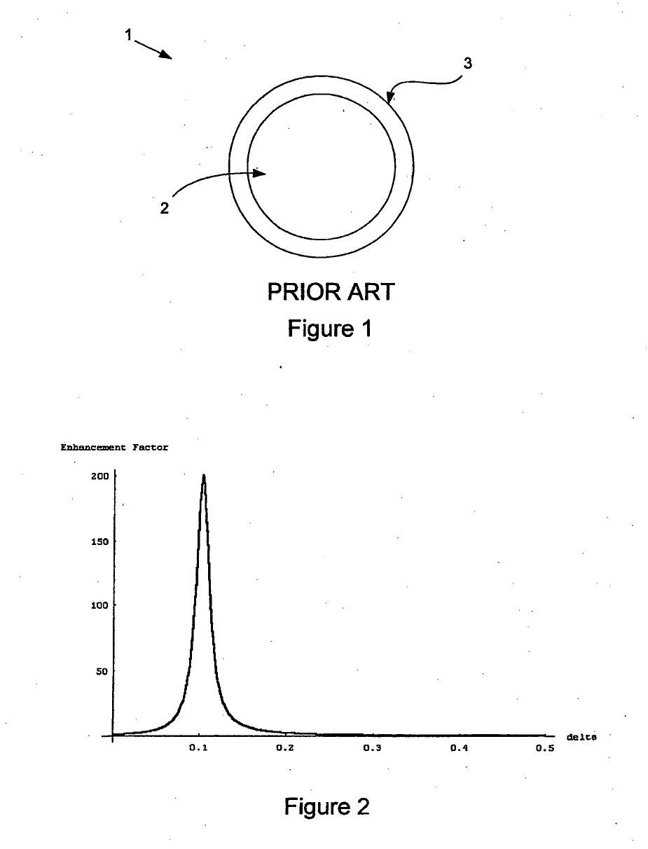

### DETAILED DESCRIPTION

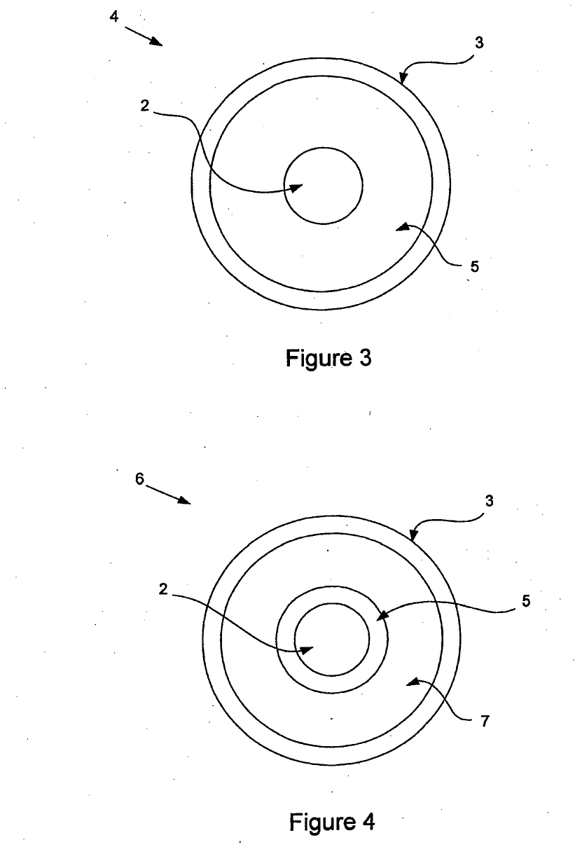

Referring to FIG. 3, a quantum dot structure 4 according to a first embodiment of the invention is provided in a “scotch egg” type structure, with a barrier layer 5, provided between a quantum dot 2 and a metal layer 3. The barrier layer 5 prevents charge carriers, in other words, electrons and/or holes, from leaving the quantum dot 2.

The invention allows the radius of the quantum dot 2 to be chosen to display the desired optoelectronic property required, such as absorption/gain at particular wavelengths. As noted previously, the radius of the quantum dot 2 would typically be 5 nm or less. The outer radius of the barrier layer 5 may be typically 10 times bigger than the radius of the quantum dot 2, and is preferably chosen to maximise the electric field in the quantum dot 2 while, at the same time, being large enough so that the required width of the metal layer 3 can be reliably deposited.

In an ensemble of such quantum dot structures 4, the required width of the metal layer 3 may be substantially the same for all quantum dots 2 since, in the growth of the barrier layer 5, the outer radius of the metal layer 3 can be substantially independent of the quantum dot radius. If this were not the case, then one could use size fractionation to create sub-ensembles of quantum dots 2, the quantum dots 2 in each sub-ensemble being of substantially the same size, and then carry out the growth of the barrier layers 5 and metal layers 3 separately on each sub-ensemble so as to optimise each sub-ensemble before reconstituting the original ensemble from the sub-ensembles.

In this particular example, the barrier layer 5 is formed from semiconducting material. The quantum dot 2 has a typical radius of 5 nm or less, as noted above. The outer radius of the barrier layer 5 and, therefore, the inner radius of the metal layer 3, is 7.5 nm. The metal layer 3 consists of three atomic layers of a noble metal, such as copper, gold or silver, and thus has a thickness in the range of 0.75 nm. An ensemble of such quantum dot structures 4 may thus be provided in which the radius of the quantum dot 2 varies between the quantum dot structures 4. The barrier layer 5 of each quantum dot structure 4 is then configured to give a predetermined outer radius of 7.5 nm. Each quantum dot structure 4 in the ensemble is thus provided with a metal layer 3 having the same thickness, so that each quantum dot structure 4 has the same overall dimensions.

If required, both the quantum dot 2 and barrier layer 5 are formed from semiconducting material. In this case, the composition of the barrier layer 5 would typically be a semiconductor with a band gap that is wider than that of the semiconductor from which the quantum dot 2 is composed so that the electrons and holes are still confined to the quantum dot 2. So, for example, if the quantum dot 2 is made of mercury telluride, then one might use cadmium telluride as the barrier layer 5. Since most semiconductors have similar dielectric constants in the optical region, the differences in the dielectric constant of the quantum dot 2 and the barrier materials will not usually affect the overall design significantly, in terms of the quantum dot radius and the thickness of the barrier layer 5. In the case of disparate dielectric constants the optimum structure for maximising the electric field in the quantum dot 2 could be computed taking this disparity into account.

If required, the quantum dot 2 may be formed from an insulating or a semi-insulating material instead of a semi-conductor and the barrier layer 5 may be formed from a semi-conducting, insulating or semi-insulating material. For example, a quantum dot structure could be provided in which the quantum dot 2 is an insulator or semi-insulating and the barrier layer 5 is a semiconductor. Such an arrangement may be unipolar, with the relevant electronic excitations within the quantum dot 2 occurring in only one of the conduction band or the valence band. In this case, the barrier layer 5 would only have to act as a barrier for one type of charge carrier, that is, either electrons or holes, as appropriate.

In the example of FIG. 3, the metal layer 3 is formed from a noble metal. However, another metal or another electrically conductive material with suitable properties for modifying electric fields may be used instead to form this layer 3.

In another embodiment of the invention, one or more cladding layers may be provided between the barrier layer and the metal shell. For instance, a quantum dot structure may be provided with one or more cladding layers to compensate for any lack of chemical affinity between the material used to form the barrier layer 5 and the material used to form the metal layer 3. An example of a quantum dot structure 6 with one such cladding layer 7 is shown in FIG. 4.

As in the previous example, the quantum dot 2 may be formed from an insulating, semi-insulating or semiconducting material. The barrier layer 5 is preferably formed of an insulator, a semi-conductor with a wider band gap than the material used to form the quantum dot 1 or a semi-insulating material. The cladding layer 7, or cladding layers, can be formed using semiconducting, semi-insulating or insulating material.

It would not be obvious to a person skilled in the art to try the types of structure shown in FIGS. 3 and 4 and structures with multiple cladding layers without knowledge of the present disclosure: one does not want to introduce another major stage in the nanostructure growth process without a compelling reason.

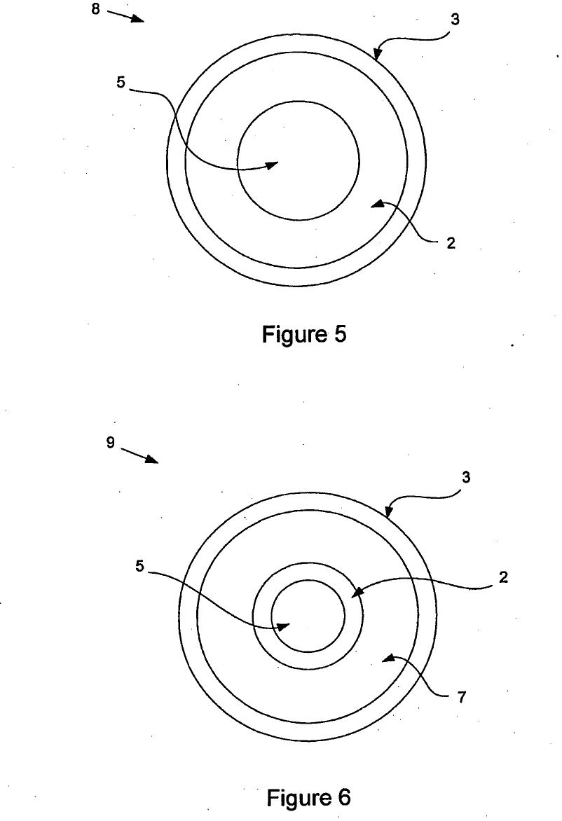

In the quantum dot structures 4, 6 of FIGS. 3 and 4, the carriers are confined in the core section, formed by quantum dot 2. However, similar quantum dot structures may be produced in which the core performs the function of the barrier layer 5 and charge carriers are confined in a surrounding region, performing the function of the quantum dot 2. Examples of such quantum dot structures are shown in FIGS. 5 and 6.

FIG. 5 depicts a quantum dot structure 8 according to a third embodiment of the invention, comprising a barrier 5, surrounded by a charge carrier confinement region 2 and a metal layer 3. In order to prevent charge carriers entering the barrier 5, the barrier 5 is formed of a material with a band gap that is wider than that of the material used to form the charge carrier confinement region 2. The metal layer 3 also acts to wholly or substantially confine the charge carriers to the charge carrier confinement region 2.

FIG. 6 depicts a quantum dot structure 9 according to a fourth embodiment of the invention. In a similar manner to the quantum dot structure 8 of FIG. 5, the quantum dot structure 9 comprises a barrier 5 surrounded by a charge carrier confinement region 2. One or more cladding layers 7 are provided between the charge carrier confinement region 2 and the metal layer 3, in order to compensate for any lack of chemical affinity between the charge carrier confinement region 2 and metal layer 3. The combination of the cladding layer 7 and the metal layer 3 also act to wholly or substantially confine the charge carriers to the charge carrier confinement region 2.

As described above in relation to the first embodiment, the dimensions of the charge carrier confinement region 2 are selected so that the quantum dot structure provides the desired optical properties, while the dimensions of the barrier 5 are chosen so that the combined dimensions of the charge carrier confinement region and the barrier 5 are large enough so that the required width of the metal layer 3 can be reliably deposited.

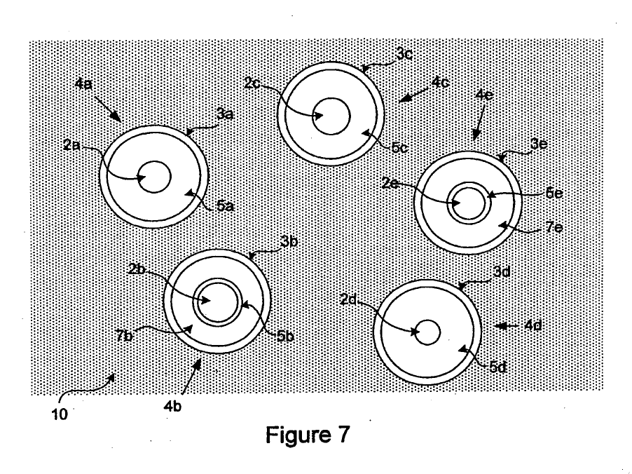

As discussed above in relation to the first embodiment, an ensemble of quantum dot structures may be provided in which the quantum dots 2 have various radii but the thicknesses of the electrically conductive layers 3 and the overall dimensions of the structures 4, 6 are substantially uniform. FIG. 7 shows an ensemble of quantum dot structures 4a-4e which, in this example, correspond to the first embodiment, shown in FIG. 3. The quantum dots 2a, 2b, 2c, 2d, 2e of these structures have various radii. However, their respective barrier layers 5a-5e and, where provided, cladding layers 7b, 7e are configured so that the inner radii of the metal layers 3a-3e are substantially uniform across the ensemble. As the thickness of the metal layers 3a-3e of the quantum dot structures 4a-4e is substantially the same across the ensemble, the overall dimensions of the quantum dot structures 4a-4e are also substantially uniform. Such an ensemble may be produced using the size fractionation process described above.

Such ensembles may be produced in which the quantum dot structures correspond to any one of those shown in FIGS. 3 to 6, or a combination of two or more of the different types of quantum dot structures 4, 6, 8, 9 shown in FIG. 3 to 6.

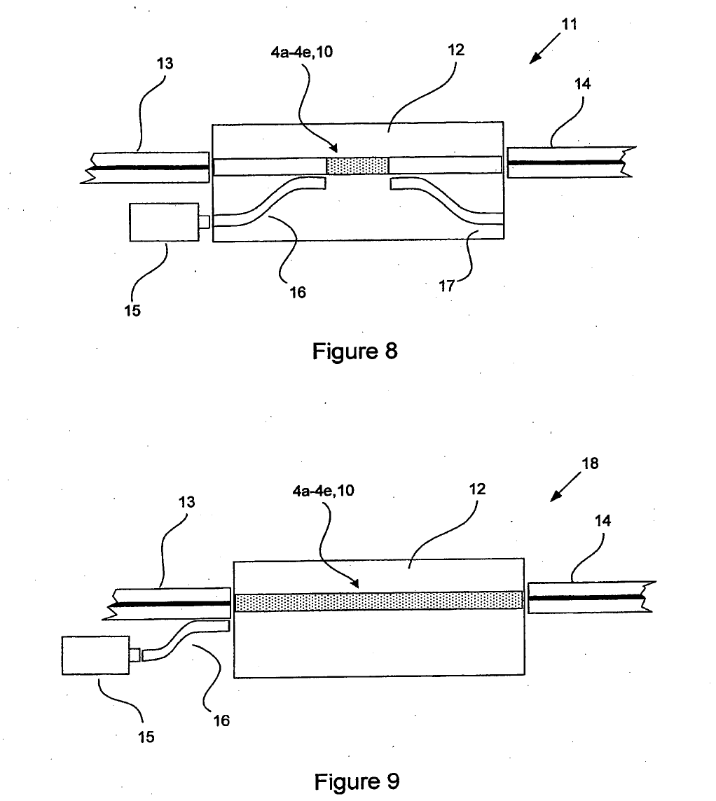

The ensemble of quantum dot structures may be suspended in a host medium 10, such as a glass or a polymer, and used in an amplifier. FIGS. 8 and 9 depict examples of amplifiers 11, 18 comprising the ensemble 4a-4e suspended in the host medium 10 and disposed in or on a substrate 12.

A laser 15 provides pumping radiation to excite electron-hole pairs within the quantum dots 2. The laser may be a semiconductor laser such as the pump lasers typically used to pump erbium doped fibre amplifiers.

In the amplifier 11 of FIG. 8, the pumping radiation is coupled to the quantum dot structures 4a-4e via a waveguide 16. Excess pumping radiation may be discharged through coupling to a second waveguide 17.

In the amplifier 18 of FIG. 9, the waveguide 16 is coupled to an optical fibre 13 through which input optical radiation is directed into the host medium 10.

In both examples, the substrate 12 is configured so that input optical radiation from optical fibre 13, is guided through the host medium 10, where it is amplified through interactions with the quantum dots 2 within said quantum dot structures 4a-4e. The amplified light is then output through a second optical fibre 14. As, in these particular examples, the quantum dots 2 of the quantum dot structures 4a-4e have different radii, the amplifier is capable of amplifying light at multiple wavelengths simultaneously.

The quantum dot structures shown in FIGS. 3,4, 5 and 6 are examples only of possible embodiments of the invention. For instance, FIGS. 3, 4, 5 and 6 and the discussion above, have been based on idealised structures, in this case, spherically symmetric structures. But those knowledgeable in optics and electromagnetic theory will appreciate that the central feature of the present invention, the importance of the thickness of the metal layer and the size of the region enclosed by it in determining their response to electromagnetic fields, is not dependent on idealised spherical geometry. Such people will appreciate that the enhancement of the electric field is brought about substantially by the mobility of the electrons in the metal layer and the existence of such enhancements is not dependent on spherical symmetry. For example, the quantum dots may be formed with ellipsoidal, cylindrical or other shaped structures. The optimum design in any given circumstance will be found by either experimental trial and error or by detailed mathematical modelling or a judicious combination of thereof.

1. A composite quantum dot structure comprising:
a charge carrier confinement region formed of a first material;
a barrier, formed of a second material other than the first material and arranged to confine charge carriers within the charge carrier confinement region; and
a layer of electrically conductive material surrounding said charge carrier confinement region and said barrier.

2. A quantum dot structure according to claim 1, wherein said first material is a semiconductor.

3. A quantum dot structure according to claim 1, wherein said second material is a semiconductor.

4. A quantum dot structure according to claim 3, wherein the second material has a band gap wider than that of the first material.

5. A quantum dot structure according to claim 1, wherein said first material is an insulator.

6. A quantum dot structure according to claim 1, wherein said second material is an insulator.

7. A quantum dot structure according to claim 1, wherein said first material is a semi-insulator.

8. A quantum dot structure according to claim 1, wherein said second material is a semi-insulator.

9. A quantum dot structure according to claim 1, wherein said first material is an insulator and said second material is a semi-insulator.

10. A composite quantum dot structure according to claim 1, wherein said barrier surrounds said charge carrier confinement region.

11. A composite quantum dot structure according to claim 1, wherein said charge carrier confinement region surrounds said barrier.

12. A quantum dot structure according to claim 10, further comprising a cladding layer located between said barrier and said layer of electrically conductive material.

13. A quantum dot structure according to claim 11, further comprising a cladding layer located between said charge carrier confinement region and said layer of electrically conductive material.

14. A quantum dot structure according to claim 12, wherein said cladding layer is formed of a semiconducting material.

15. A quantum dot structure according to claim 12, wherein said cladding layer is formed of an insulating material.

16. A quantum dot structure according to claim 12, wherein said cladding layer is formed of a semi-insulating material.

17. A quantum dot structure according to claim 12, comprising multiple cladding layers, wherein at least two of said cladding layers are formed of different materials.

18. A quantum dot structure according to claim 12, wherein said electrically conductive material is a metal.

19. A quantum dot structure according to claim 18, wherein said metal is a noble metal.

20. A quantum dot structure according to claim 1, that is substantially spherically symmetrical.

21. A quantum dot structure according to claim 20, wherein an outer radius of the barrier is approximately ten times a radius of the charge carrier confinement region.

22. A quantum dot structure according to claim 20, wherein the charge carrier confinement region has a radius of 5 nm or less.

23. An optical amplifier comprising one or more quantum dot structures according to claim 1.

24. A laser comprising one or more quantum dot structures according to claim 1.

25. A light-emitting diode comprising one or more quantum dot structures according to claim 1.

26. An optical switch comprising one or more quantum dot structures according to claim 1.

27. An ensemble of quantum dot structures according claim 1, wherein:
at least a first one of said quantum dot structures has a charge carrier confinement region having first dimensions and a barrier having second dimensions;
at least a second one of said quantum dot structures has a charge carrier confinement region having third dimensions and a barrier having fourth dimensions, the third dimensions being different from the first dimensions and the fourth dimensions being different from the second dimensions; and
the layers of electrically conductive material of said first and second quantum dot structures having substantially the same dimensions.

28. A method of producing a composite quantum dot structure comprising:
providing a charge carrier confinement region formed of a first material;
providing a barrier arranged to confine charge carriers to said charge carrier confinement region, formed of a second material other than the first material; and
providing a layer of electrically conductive material surrounding said charge carrier confinement region and said barrier.

29. A method according to claim 28, wherein said step of providing a barrier comprises surrounding said charge carrier confinement region with said barrier.

30. A method according to claim 29, comprising:
providing at least one cladding layer between said barrier and said layer of electrically conductive material.

31. A method according to claim 28, wherein said step of providing a charge carrier confinement region comprises surrounding said barrier with said charge carrier confinement region.

32. A method according to claim 31, comprising:
providing at least one cladding layer between said charge carrier confinement region and said layer of electrically conductive material.

33. A method according to claim 30, wherein said step of providing at least one cladding layer comprises providing multiple cladding layers, at least two of said cladding layers being formed of different materials.

34. A method according to claim 28, comprising:
incorporating said quantum dot structure in a host material.

35. A method according to claim 29, comprising:
physically dividing an ensemble of charge carrier confinement regions into a plurality of sub-ensembles; and
reconstituting said ensemble of charge carrier confinement regions;
wherein the steps of providing said barrier and providing said layer of electrically conductive material are performed on the sub-ensembles of charge carrier confinement regions, before said step of reconstituting said plurality of charge carrier confinement regions.

36. A method according to claim 31, comprising:
physically dividing an ensemble of barriers into a plurality of sub-ensembles; and
reconstituting said ensemble of barriers;
wherein the steps of providing said charge carrier confinement region and providing said layer of electrically conductive material are performed on the sub-ensembles of barriers, before said step of reconstituting said plurality of barriers.

37. A method according to claim 35, wherein said physical division of said ensemble is performed using a size fractionation process.

38. An ensemble of quantum dot structures comprising:
a first quantum dot structure comprising a charge carrier confinement region formed of a first material and having first dimensions and a barrier formed of a second material and having second dimensions, arranged to confine charge carriers to said charge carrier confinement region, wherein one of said charge carrier confinement region and said barrier surrounds the other of said charge carrier confinement region and said barrier, said first material being different from said second material; and
a second quantum dot structure comprising a charge carrier confinement region formed of the first material and having third dimensions and a barrier formed of the second material and having fourth dimensions, arranged to confine charge carrier to said charge carrier confinement region, wherein one of said charge carrier confinement region and said barrier surrounds the other of said charge carrier confinement region and said barrier, said third dimensions being different from said first dimensions and said fourth dimensions being different from said second dimensions;
wherein each of said first and second quantum dot structures comprise a layer of electrically conductive material surrounding said one of said charge carrier confinement region and said barrier, the dimensions of said layers of electrically conductive material of the first and second quantum dot structures being substantially the same.

39. An ensemble according to claim 38, wherein at least one of said first and second quantum dot structures comprises a cladding layer located between the layer of electrically conductive material and either said barrier or said charge carrier confinement region.

40. An optical amplifier comprising an ensemble of quantum dot structures according to claim 38.

41. A method of producing an ensemble of quantum dot structures comprising:
providing a plurality of charge carrier confinement regions formed of a first material, at least a first one of said charge carrier confinement regions having first dimensions and at least a second one of said charge carrier confinement regions having second dimensions, wherein the first dimensions are not equal to the second dimensions;
providing a plurality of barriers, each one of said barriers being arranged to confine charge carriers to a respective one of said charge carrier confinement regions, the barriers being formed of a second material other than the first material; and
providing a plurality of layers of electrically conductive material;
wherein:
in each quantum dot structure, one of said barrier and said charge carrier confinement regions surrounds the other of said barrier and said charge carrier confinement region, the layer of electrically conductive material surrounding said one of said barrier and said charge carrier confinement region; and
said first, second, third and fourth dimensions are selected so that the dimensions of said layers of electrically conductive material is substantially the same.

42. A method according to claim 40, wherein at least one of said first and second quantum dot structures comprises at least one cladding layer located between the layer of electrically conductive material and said one of said barrier and said charge carrier confinement region.
